(19) United States
(12) Patent Application Publication
(10) Pub. No.: US 2009/0085207 A1
(43) Pub. Date: Apr. 2, 2009

(54) Ball grid array substrate package and solder pad

(75) Inventor: Akira Matsunami, Beppu (JP)

Correspondence Address: TEXAS INSTRUMENTS INCORPORATED, P O BOX 655474, M/S 3999, DALLAS, TX, 75265, US

(73) Assignee: Texas Instruments, Inc.

(21) Appl. No.: 11/904,841

(22) Filed: Sep. 28, 2007

(51) Int. Cl. H01L 23/52; H01L 21/00

(52) U.S. Cl. 257/738; 438/106; 257/E23.141

(57) ABSTRACT

The invention provides ball grid array assemblies and methods for their manufacture, with improved characteristics favoring the formation of secure metallurgical solder pad to solder ball joints. In disclosed preferred embodiments of ball grid array assemblies, substrates, and methods according to the invention, solder pads are provided with metal blocks comprising a layer primarily of nickel plated with an outer metal layer comprising primarily gold.

### TECHNICAL FIELD

The invention relates to electronic semiconductor integrated circuits (ICs) and manufacturing. More particularly, the invention relates to BGA (ball grid array) packages, substrate assemblies, solder pads, and to methods related to their manufacture.

### BACKGROUND OF THE INVENTION

A ball grid array (BGA) is a surface-mountable IC package that utilizes an array of metal spheres or balls attached to a substrate surface for providing external electrical connections. The balls are made from solder, and are attached to planar metallic solder pads provided in a laminated substrate at a surface of the package. The IC of the BGA is electrically connected to the substrate by wirebond or flip-chip connections. Internal electrical traces within the substrate route the connections to the solder pads. The BGA package is favored for its high interconnection density and relatively small size. Additionally, incorporating a BGA onto a larger assembly, such as a circuit board, is made more convenient in comparison to leaded counterparts of the same pin count due to the characteristic that the solder needed for attachment to other components, e.g., board mounting, is provided in the form of the solder balls. The solder balls are typically factory-applied in precise form and size during the process of assembling the BGA. The pre-mounted solder balls tend to ‘self-align’ to their attachment sites during board mounting.

The potential benefits of BGA packages are diminished or lost when solder balls fail to adhere to solder pads during manufacturing, or drop off subsequent to manufacturing. These problems are exacerbated by the difficulty of inspecting the balls and solder joints for defects once the BGA has been soldered onto a board. In order to provide good solder ball attachment, efforts are made in the arts to use solder pads made from metals and/or alloys that provide good adhesion to the solder balls as well as high electrical conductivity. It is conventional to use copper or copper alloy solder pads, and to apply metal and/or alloy plating to the solder pads in an effort to improve the adhesion of solder to the surface. Nevertheless, solder ball connections to solder pads on the surface of a BGA sometimes suffer from insufficient adhesion, lack of mechanical strength, and lack of long-term durability. Confronted with the inherent limitations in available solder pad area and the limited selection of suitable solder pad materials, increasing the strength and reliability of the solder joints remains a challenge to practitioners in the arts.

Due to these and other technical challenges, BGA substrate and package assemblies with solder pads enhanced for improved solder joints, and related methods for their manufacture, would be useful and advantageous in the arts. The present invention is directed to overcoming, or at least reducing the effects of one or more of the problems extant in the art.

### SUMMARY OF THE INVENTION

In carrying out the principles of the present invention, in accordance with preferred embodiments thereof, the invention provides BGA substrates and packages, and methods for their manufacture, with improved solder pad characteristics for secure solder ball attachment.

According to one aspect of the invention, a preferred embodiment of a ball grid array assembly includes a substrate with metallic solder pads for receiving solder balls. An integrated circuit is coupled to the substrate and encapsulated. Each metallic solder pad further includes one or more projecting metal blocks on its surface.

According to another aspect of the invention, a ball grid array assembly includes metal blocks made using layers including nickel and gold projecting from the solder pads.

According to another aspect of the invention, in a preferred embodiment, a ball grid array assembly includes one or more metal blocks affixed to the solder pads of a substrate. The blocks are made from metal blocks projecting from the solder pad surfaces and are substantially comprised of nickel metallurgically bonded to the solder pads.

According to yet another aspect of the invention, in an alternative preferred embodiment, a ball grid array assembly includes metal blocks formed on the solder pads of the ball grid array by plating and etching.

According to another aspect of the invention, a preferred method for making a ball grid array assembly includes steps for providing a substrate having an integrated circuit site on one surface for receiving an integrated circuit, and a number of solder pads on the opposing surface. An integrated circuit is provided at the integrated circuit site. The solder pads are plated with a metal layer comprising nickel, then the plated layer is etched to form projecting blocks on each solder pad. Subsequently, the etched blocks are plated with a layer comprising gold.

According to still another aspect of the invention, in alternative embodiments, methods include steps for plating the solder pads and projecting blocks with a low-melting point alloy consisting of two or more metals selected from the group: palladium, gold, silver, copper, and tin.

According to yet another aspect of the invention, a method for making a ball grid array assembly includes steps of providing a substrate having an integrated circuit site on one surface for receiving an integrated circuit and solder pads on the opposing surface. A number of metal blocks are formed on each of the solder pads. Thereafter, the solder pads and attached blocks are plated with a metal layer including gold. Steps also include affixing an integrated circuit to the integrated circuit site.

According to still another aspect of the invention, methods for making a ball grid array substrate assembly according to preferred embodiments include steps for plating projecting metal blocks onto the solder pads.

The invention has advantages including but not limited to improving BGA package strength and reliability, and improving electrical and mechanical connections at BGA substrate solder pads. These and other features, advantages, and benefits of the present invention can be understood by one of ordinary skill in the arts upon careful consideration of the detailed description of representative embodiments of the invention in connection with the accompanying drawings.

### BRIEF DESCRIPTION OF THE DRAWINGS

The present invention will be more clearly understood from consideration of the following detailed description and drawings in which:

FIG. 1 is a cutaway side view of an example of a preferred embodiment of a BGA package according to the invention;

FIG. 2 is a macro cutaway side view showing a solder pad portion of the preferred embodiment of a BGA package according to the invention shown in FIG. 1;

FIG. 3A is a macro cutaway side view showing steps in the manufacture of a solder pad portion of a preferred embodiment of a BGA package according to methods of the invention;

FIG. 3B is a macro cutaway side view showing steps in the manufacture of a solder pad portion of a preferred embodiment of a BGA package according to methods of the invention;

FIG. 3C is a macro cutaway side view showing steps in the manufacture of a solder pad portion of a preferred embodiment of a BGA package according to methods of the invention;

FIG. 4A is a macro cutaway side view showing steps in the manufacture of a solder pad portion of a preferred embodiment of a BGA package according to methods of the invention;

FIG. 4B is a macro cutaway side view showing steps in the manufacture of a solder pad portion of a preferred embodiment of a BGA package according to methods of the invention;

FIG. 4C is a macro cutaway side view showing steps in the manufacture of a solder pad portion of a preferred embodiment of a BGA package according to methods of the invention;

FIG. 5 is a bottom view of a preferred embodiment of a solder pad according to the invention;

FIG. 6 is a bottom view of a preferred embodiment of a solder pad according to the invention;

FIG. 7 is a bottom view of a preferred embodiment of a solder pad according to the invention; and

FIG. 8 is a bottom view of a preferred embodiment of a solder pad according to the invention.

References in the detailed description correspond to like references in the various drawings unless otherwise noted. Descriptive and directional terms used in the written description such as first, second, top, bottom, upper, side, etc., refer to the drawings themselves as laid out on the paper and not to physical limitations of the invention unless specifically noted. The drawings are not to scale, and some features of embodiments shown and discussed are simplified or amplified for illustrating the principles, features, and advantages of the invention.

### Description of Preferred Embodiments

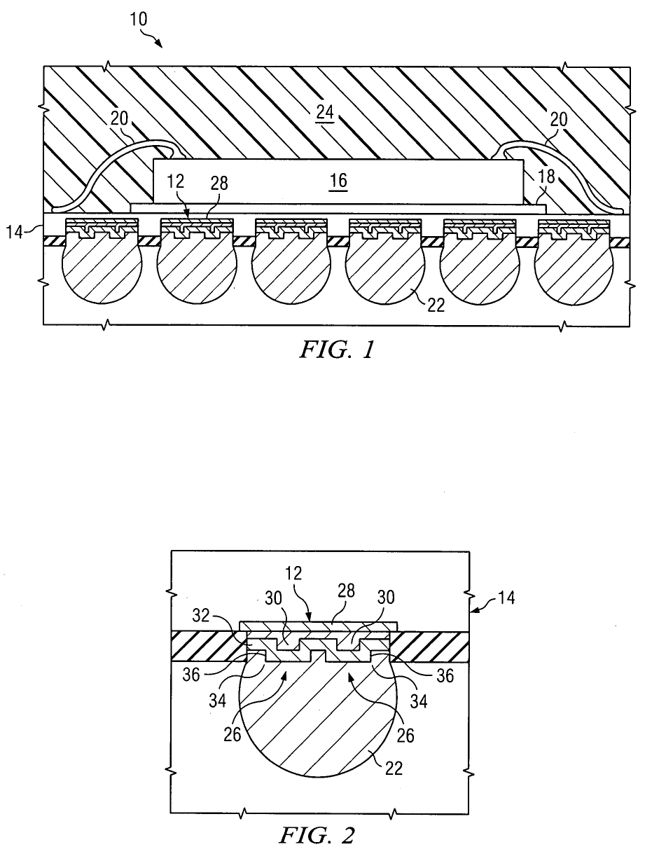

The invention provides improved BGA substrates, packages, and methods related to their manufacture, and solder pads with improved metallurgical bonding characteristics and configured for favorable bond formation, strength, and durability. Referring initially to FIG. 1, a simplified cutaway side view of an example of a preferred embodiment of a BGA package 10 incorporating improved solder pads 12 according to the invention is shown. A substrate 14 forms the foundation of the BGA package 10. An electronic device, such as an IC 16, is affixed to the substrate 14 using suitable adhesive 18 as known in art and is electrically connected to electrical paths (not shown) in the substrate 14, preferably using bond wires 20 or flip-chip connections (not shown) familiar in the arts. Solder balls 22 are attached to the solder pads 12 for making electrical connections between the BGA 10 and the outside world (not part of the invention). Typically, encapsulant 24 encapsulates the IC 16, a surface of the substrate 14, and any electrical connections between, e.g. the bond wires 20, in order to protect them from the hazards of the environment. The solder pads 12, shown in greater detail in the partial cutaway side view of FIG. 2, include one or more projecting metal blocks 26. The metal blocks 26 are made from metals or alloys according to the methods described. Preferably, the solder pads 12 are constructed beginning with exposed areas 28 of copper or copper alloy on the substrate 14 surface. In preferred embodiments of the invention, multiple metal blocks 26 are established on the surface 28 of each of the solder pads 12. Preferably, the blocks 26 and the surrounding area of the solder pads 12 are plated with one or more relatively low melting-point alloys in order to enhance the formation of strong and durable metallurgical bonds when the solder balls 22 are attached. Although other metals and various alloys may be used, in presently preferred embodiments of the invention, a base layer primarily of nickel 30 is used with outer layer 32 primarily of gold. Other metals and alloys may also be used for the base layer 30 and/or outer layer 32. For example, in alternative embodiments, alloys made from combinations containing palladium, gold, tin, silver, and copper, may be used.

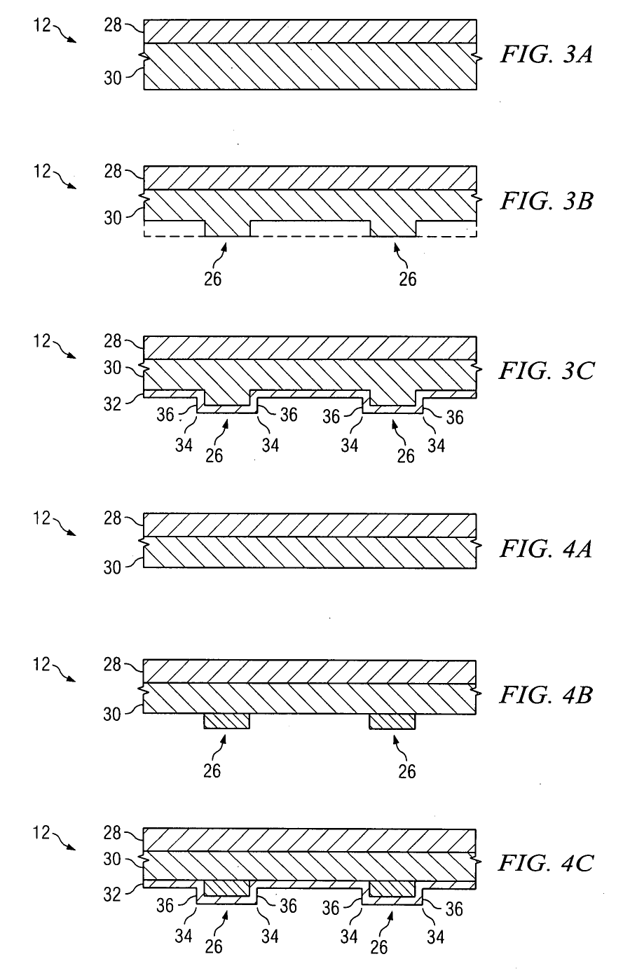

Preferably, the block 26 is formed to project to a height of about 5 to 10 micrometers above the surface of the remainder of the solder pad 12. The base layer 30, in this example primarily nickel, is preferably plated with an outer layer 32 primarily of gold as further described with reference to the alternative methods depicted in FIGS. 3A-3C and 4A-4C. As illustrated in FIG. 3A, in a preferred method of the invention, the base layer 30, primarily nickel, is applied to the solder pad surface 28, usually copper or copper-alloy, by plating as known in the arts. The base layer 30 is preferably applied to within the range of about 15-20 micrometers in thickness. Now referring primarily to FIG. 3B, the base layer 30 is masked and etched in order to form a pattern of blocks 26 on the surface of the solder pad 12. Preferably, the blocks 26 are from 5 to 10 micrometers in height. Subsequent to the formation of the blocks 26, the entire solder pad structure 12 is then plated, preferably with an outer layer 32 containing a significant proportion of gold to a thickness of about 0.5 to 0.75 micrometers, as shown in FIG. 3C. Variations are possible within the scope of the invention, for example with respect to the thickness of the layers 30, 32, and the degree of purity of the gold and nickel. It has been found that practicing the invention within the preferred ranges provides advantages in the formation of secure metallurgical bonds between the solder pad so structured and a typical solder ball brought into contact with the same.

An alternative method of practicing the invention is shown beginning with FIG. 4A, in which a base layer 30, preferably nickel, is plated on to the initial surface 28 of the solder pad 12, preferably within the range of about 5 to 15 micrometers in thickness. Referring to FIG. 4B, metal blocks 26, preferably high in nickel content, are plated onto the base layer 30. The blocks 26 are preferably approximately 5 to 10 micrometers in thickness. The blocks 26 are formed in a suitable arrangement, such as a grid pattern for example. After the blocks 26 are formed on the base layer 30, the entire solder pad structure 12 is plated with an outer layer 32, preferably substantially of gold.

The possible alternative embodiments of the invention are numerous and cannot all be shown. The steps in the preferred embodiments shown and described may be performed in various combinations. For example, potential pattern, plating, and shape variations are legion. Regardless of the variation of the methods used, the surfaces of the solder pads 12 of BGAs using the invention are made to deviate from the smooth planar surface generally known in the art by the incorporation of blocks 26 forming a projecting, non-planar pattern. The blocks 26 provide numerous edges 34 advantageous for the subsequent formation of metallurgical bonds when brought into contact with molten solder balls upon reflow. The blocks 26 also provide additional surfaces 36 to which the solder balls 22 may adhere. The metallic composition of the enhanced solder pads 12 of the invention also improve metallurgical bonding due to the interaction of the included metals, e.g., nickel and gold, with the metals of the solder balls 22, generally a combination including nickel, tin, and silver.

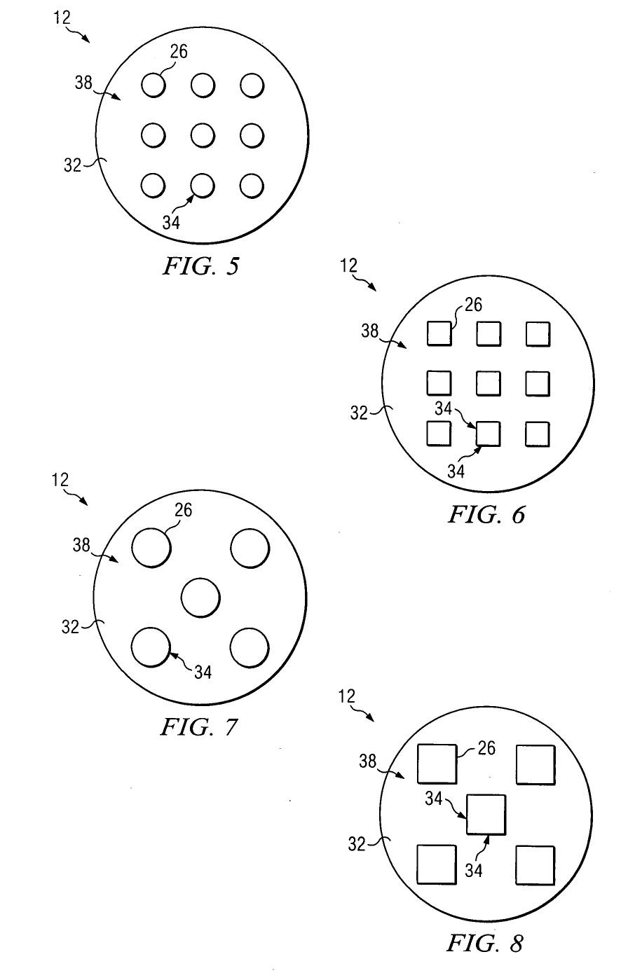

Several alternative examples of block 26 patterns 38 which may be used in the implementation of the solder pads 12 of the invention are shown in FIGS. 5 through 8. As shown, the surface of the solder pad 12 is provided with a plated outer layer 32, and edges 34 and surfaces of the blocks 26 are available to assist in forming bonds with solder balls (not shown) ultimately applied to the solder pads 12. The blocks 26 may be arranged in various patterns 38, a few representative examples of which are shown in FIGS. 5 through 8. A grid pattern 38 may be used, as illustrated in FIGS. 5 and 6, or a non-grid pattern 38 may be used, e.g., FIGS. 7 and 8. As also shown, the blocks 26 may be made in the form of rectangular “boxes” as in FIGS. 5 and 7, or in other shapes, such as the “discs” depicted in FIGS. 6 and 8. Other patterns or shapes, or single blocks, may also be used be used to provide increased edges 34 and surface area 36 without departure from the principals of the invention.

The methods and apparatus of the invention provide one or more advantages including but not limited to improved solder pad—to solder ball bond strength and stability. Improved solder pad bond strength gained when using the invention may also result in improvements in overall BGA package strength and durability due to reductions in stresses on mechanical bonds elsewhere in the package. Additionally, increased mechanical strength and durability in packages using the invention in some instances may be used to provide increased design flexibility beneficial to the implementation of other electrical and mechanical connections within the package. While the invention has been described with reference to certain illustrative embodiments, those described herein are not intended to be construed in a limiting sense. For example, variations or combinations of steps or materials in the embodiments shown and described may be used in particular cases without departure from the invention. Various modifications and combinations of the illustrative embodiments as well as other advantages and embodiments of the invention will be apparent to persons skilled in the arts upon reference to the drawings, description, and claims.

I claim:

1. A ball grid array assembly comprising:
a substrate having a plurality of metallic solder pads for receiving solder balls;
an integrated circuit operably coupled to the substrate; and
encapsulant encapsulating the integrated circuit;
wherein a plurality of the solder pads each further comprises at least one metal block protruding from the surface of the solder pad.

2. The ball grid array assembly according to claim 1 wherein the metal blocks protruding from the solder pad surfaces further comprise a combination of nickel and gold.

3. The ball grid array assembly according to claim 1 wherein the metal blocks protrude within the range of about 5 to 10 micrometers from the solder pad surfaces.

4. The ball grid array assembly according to claim 1 wherein the metal blocks further comprise nickel within the range of about 5 to 15 micrometers in thickness.

5. The ball grid array assembly according to claim 1 wherein the metal blocks further comprise gold within the range of about 0.5 to 0.75 micrometers in thickness.

6. The ball grid array assembly according to claim 1 wherein the metal blocks protruding from the solder pad surfaces further comprise metal plating.

7. The ball grid array assembly according to claim 1 wherein the metal blocks protruding from the solder pad surfaces further comprise nickel plating.

8. The ball grid array assembly according to claim 1 further comprising a plurality of metal blocks projecting from the solder pads in a grid pattern.

9. The ball grid array assembly according to claim 1 further comprising a plurality of approximately rectangular metal blocks projecting from the solder pads.

10. The ball grid array assembly according to claim 1 further comprising a plurality of approximately disc-shaped metal blocks projecting from the solder pads.

11. A method for making a ball grid array assembly comprising the steps of:
providing a substrate, the substrate having an integrated circuit site on one surface for receiving an integrated circuit, the substrate also having a plurality of solder pads on the opposing surface;
plating each of the solder pads with a metal layer comprising nickel; then,
etching one or more portions of each plated nickel layer to form a plurality of blocks projecting from each solder pad; and subsequently,
plating each etched nickel layer with an outer layer comprising gold; and
affixing an integrated circuit to the integrated circuit site.

12. The method for making a ball grid array assembly according to claim 11 wherein the metal blocks are formed to project within the range of about 5 to 15 micrometers from the solder pad surfaces.

13. The method for making a ball grid array assembly according to claim 11 wherein the step of plating the etched solder pads comprises applying a layer comprising gold to within the range of about 0.5 to 0.75 micrometers in thickness.

14. The method for making a ball grid array assembly according to claim 11 wherein etching the plated solder pads further comprises steps for forming projecting blocks arranged in grid patterns.

15. The method for making a ball grid array assembly according to claim 11 wherein etching the plated solder pads further comprises steps for forming a plurality of approximately rectangular metal blocks on the solder pads.

16. The method for making a ball grid array assembly according to claim 11 further comprising steps for forming a plurality of approximately disc-shaped metal blocks on the solder pads.

17. The method according to claim 11 further comprising the step of plating the solder pad blocks with a low-melting point alloy consisting of two or more metals selected from the group: gold, silver, copper, tin, palladium.

18. A method for making a ball grid array substrate assembly comprising the steps of:
providing a substrate, the substrate having an integrated circuit site on one surface for receiving an integrated circuit, the substrate also having a plurality of solder pads on the opposing surface;
forming one or more metal blocks comprising nickel to protrude from each of the solder pads; and
plating the solder pads and protruding blocks with an outer layer comprising gold.

19. The method for making a ball grid array substrate assembly according to claim 18 wherein the metal blocks are formed to protrude within the range of about 5 to 15 micrometers from the solder pads.

20. The method for making a ball grid array substrate assembly according to claim 18 wherein the step of plating the solder pads and protruding metal blocks comprises applying an outer layer comprising gold to within the range of about 0.5 to 0.75 micrometers in thickness.

21. The method for making a ball grid array substrate assembly according to claim 18 further comprising steps for forming the plurality of metal blocks protruding from the solder pads arranged in a grid pattern.

22. The method for making a ball grid array substrate assembly according to claim 18 further comprising the step of plating the solder pads and protruding blocks with a low-melting point alloy consisting of two or more metals selected from the group: gold, silver, copper, tin, palladium.
